(19) United States
(12) Patent Application Publication
(10) Pub. No.: US 2026/0090466 A1
(43) Pub. Date: Mar. 26, 2026

(54) TECHNOLOGIES FOR A STACKED INTEGRATED CIRCUIT PACKAGE

(71) Applicant: Intel Corporation, Santa Clara, CA (US)

(72) Inventors: Eng Huat Goh, Ayer Itam (MY); Seok Ling Lim, Bukit Mertajam (MY); Chin Mian Choong, Georgetown (MY); Yean Ling Soon, Butterworth (MY); Kavitha Nagarajan, Bangalore (IN); Min Suet Lim, Gelugor (MY); Jackson C.P. Kong, Tanjung Tokong (MY)

(73) Assignee: Intel Corporation, Santa Clara, CA (US)

(21) Appl. No.: 18/893,369

(22) Filed: Sep. 23, 2024

(51) Int. Cl. H01L 25/18; H01L 23/00; H01L 23/538

(52) U.S. Cl. CPC H10W 90/00; H10W 42/121; H10W 70/611; H10W 70/65; H10W 70/685; H10W 90/722; H10W 90/724

(57) ABSTRACT

Technologies for stacked integrated circuit packages are disclosed. In an illustrative embodiment, an integrated circuit package, such as a processor, includes a primary circuit board and an auxiliary circuit board. Components such as processor dies and memory packages may be mounted on the top side of the primary circuit board, and the auxiliary circuit board may be mounted on the bottom side of the primary circuit board. The auxiliary circuit board may include an array of contacts to interface with a motherboard. The top side of the primary circuit board may require a relatively large area to support the processor dies and memory packages. The auxiliary circuit board may have a smaller area due to a smaller number of contacts needed with the motherboard. The additional area on the bottom side of the primary circuit board may be used to support a stiffener or other components.

### BACKGROUND

Demand for higher-performance processors for tasks such as artificial intelligence is ever-increasing. One approach for improving the performance of certain tasks is to increase the amount of on-package memory to meet memory bandwidth requirements. Memory packages such as dynamic random access memory (DRAM) packages can be large, requiring a substantial area on a package, increasing the package area. Larger area packages may also require stiffeners to mitigate warpage, further increasing the size requirements.

### BRIEF DESCRIPTION OF THE DRAWINGS

FIG. 1 is an isometric view of one embodiment of a system with an integrated circuit package on a motherboard

FIG. 2 is an isometric view of one embodiment of the integrated circuit package of FIG. 1 from a top perspective.

FIG. 3 is an isometric view of one embodiment of the integrated circuit package of FIG. 1 from a bottom perspective.

FIG. 4 is a top-down view of the system of FIG. 1.

FIG. 5 is a cross-sectional view of one embodiment of the system of FIG. 1.

FIG. 6 is an isometric view of one embodiment of a system with an integrated circuit package on a motherboard.

FIG. 7 is a cross-sectional view of one embodiment of the system of FIG. 6.

FIG. 8 is an isometric view of one embodiment of a system with an integrated circuit package on a motherboard.

FIG. 9 is a cross-sectional view of one embodiment of the system of FIG. 8.

FIG. 10 is a flowchart of one embodiment of a method of creating one embodiment of the system of FIG. 1.

FIG. 11 is a cross-sectional view of one embodiment of an apparatus at one stage of the flowchart of FIG. 10.

FIG. 12 is a cross-sectional view of one embodiment of an apparatus at one stage of the flowchart of FIG. 10.

FIG. 13 is a cross-sectional view of one embodiment of an apparatus at one stage of the flowchart of FIG. 10.

FIG. 14 is a cross-sectional view of one embodiment of an apparatus at one stage of the flowchart of FIG. 10.

FIG. 15 is a cross-sectional view of one embodiment of an apparatus at one stage of the flowchart of FIG. 10.

FIG. 16 is a cross-sectional view of one embodiment of an apparatus at one stage of the flowchart of FIG. 10.

FIG. 17 is a top view of a wafer and dies that may be included in a microelectronic assembly, in accordance with any of the embodiments disclosed herein.

FIG. 18 is a cross-sectional side view of an integrated circuit device that may be included in a microelectronic assembly, in accordance with any of the embodiments disclosed herein.

FIGS. 19A-19D are perspective views of example planar, gate-all-around, and stacked gate-all-around transistors.

FIG. 20 is a cross-sectional side view of an integrated circuit device assembly that may include a microelectronic assembly, in accordance with any of the embodiments disclosed herein.

FIG. 21 is a block diagram of an example electrical device that may include a microelectronic assembly, in accordance with any of the embodiments disclosed herein.

### DETAILED DESCRIPTION

In various embodiments disclosed herein, an integrated circuit component has a primary circuit board and an auxiliary circuit board, with the bottom side of the primary circuit board mated with the top side of the auxiliary circuit board. The integrated circuit component may be mounted on another circuit board, such as a motherboard. On the top side of the primary circuit board, various components, such as processor dies and memory packages, are mounted. On the bottom side of the auxiliary circuit board is an array of electronic contacts, such as a ball grid array or solder ball array. In an illustrative embodiment, the primary circuit board has a relatively large area in order to have enough area and electronic contacts for the processor dies, memory packages, etc. The auxiliary circuit board may require relatively less area with fewer electronic contacts to interface with the motherboard. The smaller auxiliary circuit board allows for a smaller physical interface with the motherboard while still allowing for a larger area on the primary circuit board. In some embodiments, because the auxiliary circuit board is smaller than the primary circuit board, the primary circuit board may have additional components mounted on the bottom side, such as a stiffener or memory dies. Additional embodiments are described in more detail below.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

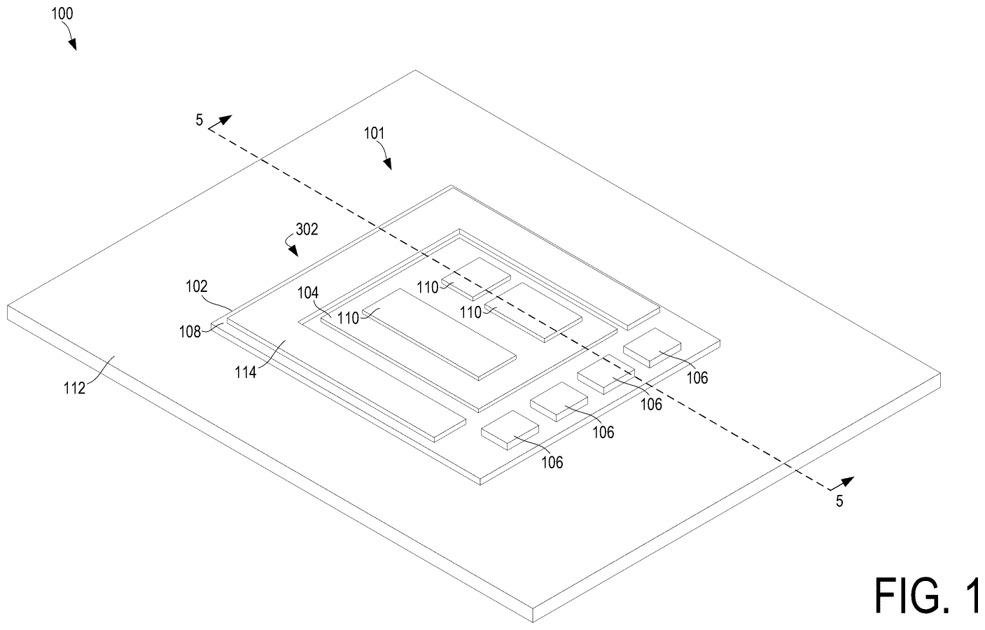

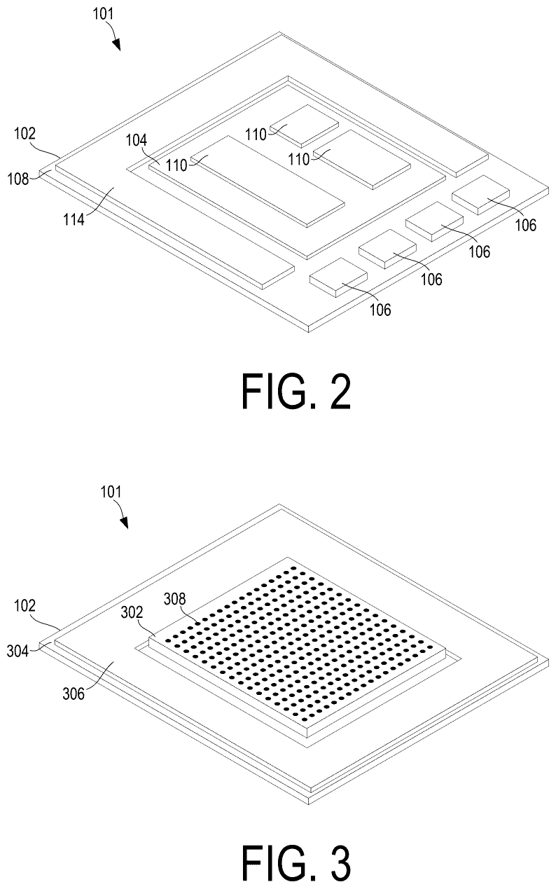

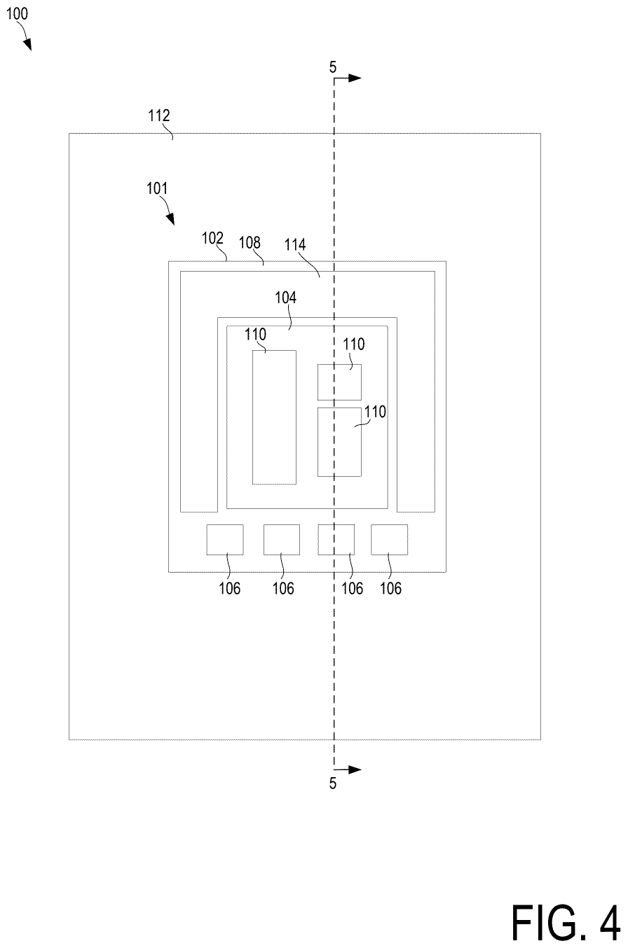

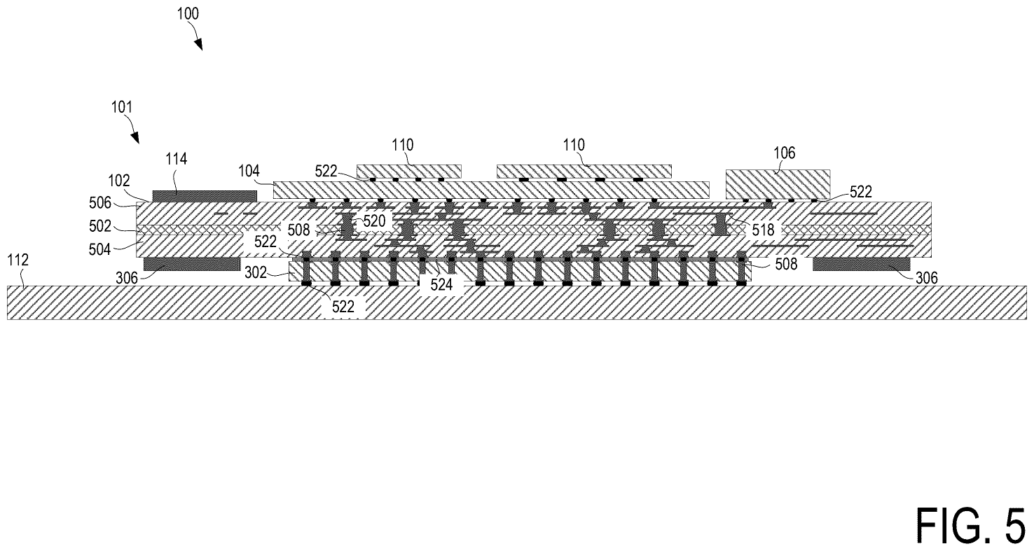

Referring now to FIGS. 1-5, in one embodiment, a system 100 includes an integrated circuit component 101 mounted on a motherboard 112. FIG. 1 shows an isometric view of the system 100, FIG. 2 shows an isometric view of the top of the integrated circuit component 101, FIG. 3 shows an isometric view of the bottom of the integrated circuit component 101, FIG. 4 shows a top-down view of the integrated circuit component 101, and FIG. 5 shows a cross-sectional view of the integrated circuit component 101. As shown in FIG. 1, a die 104 may be disposed on the top side 108 of a primary circuit board 102 of the integrated circuit component 101. The die 104 may be a processor base die 104, with additional processor dies 110 mounted on the processor base die 104. In an illustrative embodiment, memory packages 106 may be mounted on the circuit board 102. The memory packages 106 may be used to meet on-package memory bandwidth requirements for applications such as artificial intelligence (AI). A stiffener 114 may also be mounted on the primary circuit board 102.

The illustrative integrated circuit component 101 also includes an auxiliary circuit board 302 positioned between the primary circuit board 102 and the motherboard 112. The auxiliary circuit board 302 includes an array of electronic contacts 308. The illustrative auxiliary circuit board 302 has a smaller area than the primary circuit board 102. The additional space on the bottom side 304 of the primary circuit board 102 can be used to support additional components, such as a stiffener 306.

It should be appreciated that, as used herein, the “top side,” “bottom side,” etc., is an arbitrary designation used for clarity and does not denote a particular required orientation for manufacture or use. Although the illustrative embodiment described has the dies 104, 106 placed on the “top” side of the primary circuit board 102 and the auxiliary circuit board 302 on the “bottom” side of the primary circuit board 102, in some embodiments, the dies 104, 106 may be placed on the “bottom” side of the primary circuit board 102 and the auxiliary circuit board 302 may be placed on the “top” side of the primary circuit board 102.

In an illustrative embodiment, the primary circuit board 102 is a multi-layer circuit board 102 with build-up layers 504, 506 above and below a substrate core 502. The build-up layers 504, 506 may have any suitable number of layers, such as 1-10 layers each. In other embodiments, the primary circuit board 102 may be a single-layer primary circuit board 102. In an illustrative embodiment, the substrate core 502 is an inorganic core, such as a glass core. The glass core may be silicon oxide glass. In other embodiments, the glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight. In other embodiments, the substrate core 502 may be an organic core, such as a fiberglass board made of glass fibers and a resin, such as FR-4.

The thickness of the primary circuit board 102 may be any suitable thickness, such as 100 micrometers to 5 millimeters. The thickness of the substrate core 502 may be any suitable thickness, such as 50 micrometers to 2 millimeters. The primary circuit board 102 can have any suitable length and width, such as 1-500 millimeters. Although shown as a rectangle, it should be appreciated that the primary circuit board 102 may be any suitable shape and may have protrusions, cutouts, etc., in order to accommodate, fit, or touch other components of a device. In the illustrative embodiment, the primary circuit board 102 is planar. In other embodiments, the primary circuit board 102 may be non-planar.

Vias 508 in the core 502 may transport power and/or data signals through the substrate core 502. In an illustrative embodiment, the vias 508 are made of copper. In other embodiments, the vias 508 may be made of any suitable conductive material, such as tungsten, polysilicon, etc. The core 502 may have any suitable number of vias 508 extending through it, such as 1-10,000 vias 508. The vias 508 may have any suitable diameter, such as 1-500 micrometers. The vias 508 may be connected to other traces 518, vias 520, etc., on the build-up layers 504, 506 to connect to various components on the top surface or bottom surface of the primary circuit board 102. The traces 518 and vias 520 may be made of any suitable conductive material, such as copper or aluminum.

The build-up layers 504, 506 may be made of any suitable material or materials, such as any suitable dielectric that can support the traces 518, vias 520, etc. In an illustrative embodiment, the build-up layers 504, 506 may be made of a resin material filled with a filler, such as Ajinomoto build-up film (ABF).

In an illustrative embodiment, the die 104 is a processor base die 104, with additional processor dies 110 mounted on the processor base die 104, and the package 106 is a memory package, such as a DRAM memory package or neural processing unit (NPU). In other embodiments, the die 104, dies 110, and/or the packages 106 may be any suitable die or package, such as one or more processor dies, memory dies or packages, central processing units (CPUs), graphics processing units (CPUs), any other suitable processing units (xPUs), accelerator circuits, a field-programmable gate arrays (FPGA), application-specific integrated circuits (ASICs), etc. The dies 104, dies 110 and/or packages 106 may be connected to contact pads or vias 520 on the primary circuit board 102 through conductive contacts 522, such as solder balls.

The dies 104, dies 110 and/or packages 106 may have any suitable dimensions, such as a length and/or width of 1-50 millimeters and a height of 1-15 millimeters. In an illustrative embodiment, the die 104 has a length and width of 39.8 millimeters and 13.14 millimeters, respectively, the packages 106 have a length and width of 7 millimeters and 12.4 millimeters, respectively, the primary circuit board 102 has a length and width of 52.2 and 29.75 millimeters, respectively, and the auxiliary circuit board 302 has a length and width of 45.5 and 22.5 millimeters, respectively. For comparison, a similar design without an auxiliary circuit board 302 would require a primary circuit board 102 with a length and width of 57 millimeters and 32 millimeters, respectively, for a reduction in area of the primary circuit board 102 of 15%. The packages 106 may have any suitable height, such as 1-10 millimeters. In an illustrative embodiment, the packages 106 may have a larger height than the dies 104 and/or dies 110, either as individual dies or a stack of dies. In an illustrative embodiment, the area of the auxiliary circuit board 302 is less than the area of the primary circuit board 102. For example, the area of the auxiliary circuit board 302 may be, e.g., 10%-90% of the area of the primary circuit board 102.

In an illustrative embodiment, the primary circuit board 102 has a stiffener 114 mounted on the top surface 108 of the circuit board 102 and a stiffener 306 mounted on the bottom surface 304 of the circuit board 102. The stiffeners 114, 306 may have any suitable dimensions, such as a thickness of 0.5-10 millimeters and an outer length and/or width of 5-50 millimeters. The width of the stiffeners 114, 306 as measured from an outside edge to a cutout for the other components on the circuit board 102 may be any suitable width, such as 1-5 millimeters. In one embodiment, that width is 2 millimeters. In an illustrative embodiment, the stiffener 114 has a “U” shape with a cutout for the dies 104, 110, and the stiffener 306 has a rectangular shape with a cutout for the auxiliary circuit board 302. In other embodiments, the stiffeners 114, 306 may have different shapes. In some embodiments, the integrated circuit component 101 may include only a stiffener on the top side 108, only a stiffener on the bottom side 304, or no stiffener at all. The stiffeners 114, 306 may be made of any suitable material, such as iron, steel, stainless steel, aluminum, polyimide, FR-4, carbon fiber, ceramics, copper, graphite, and/or the like.

In an illustrative embodiment, the integrated circuit package 101 may require a certain amount of area for contacts 308 to communicate with the motherboard 112, and the integrated circuit package 101 may require a certain amount of area for contacts for dies 104, 110 and packages 106. In a typical design, with an area for contacts 308 to communicate with the motherboard 112 on one side of a circuit board and various dies 104, 110 and packages 106 on the other side of the circuit board, the area used for those two purposes is the same. However, in an illustrative embodiment of the integrated circuit package 101, the area for those two purposes can be different. In particular, the integrated circuit package 101 includes the auxiliary circuit board 302 mounted on the bottom side 304 of the primary circuit board 102. The auxiliary circuit board 302 interfaces with both the primary circuit board 102 and the motherboard 112. As such, part of the area of the bottom side 304 of the primary circuit board 102 may be used for contacts to communicate with the motherboard 112 through the auxiliary circuit board 302, while another part of the bottom side 304 of the primary circuit board 102 may be used for, e.g., the stiffener 306, or other components such as processor die, memory dies, memory packages, power components, etc.

In an illustrative embodiment, the circuit board 302 may be made of a similar material, with a similar design, and with similar dimensions as the circuit board 102, a description of which will not be repeated in the interest of clarity. However, it should be appreciated that, in an illustrative embodiment, the circuit board 302 has a smaller area than the circuit board 102. Additionally or alternatively, in some embodiments, the circuit board 302 may have fewer layers than the circuit board 102. For example, the circuit board 302 may only have two layers, and the contacts 308 on the bottom side of the circuit board 302 may be routed straight up through vias 508 to corresponding contacts on the top side of the circuit board 302 to connect to a corresponding solder ball 522 between the primary circuit board 102 and the auxiliary circuit board 302. In an illustrative embodiment, the auxiliary circuit board 302 may be mounted to the primary circuit board 102 using an adhesive 524, such as epoxy. The contacts 308 may be any suitable contact or array of contacts, such as a land grid array, ball grid array, pin grid array, etc. The pitch of the contacts 308 may be any suitable value, such as 0.3-1 millimeters. In an illustrative embodiment, the pitch of the contacts 308 is 0.62 millimeters. The pitch of contacts between other components, such as the circuit board 102 and the circuit board 302, or between the circuit board 102 and the dies 104 or the memory packages 106, may be any suitable value, such as 0.05-3 millimeters. In some embodiments, the height of solder balls 522 between the primary circuit board 102 and the auxiliary circuit board 302 may be controlled through a solder resist opening and solder ball size. In some embodiments, the thickness of the circuit board 102 may depend on the thickness of other components mounted on the bottom side 304 of the circuit board 102, such as the height of the stiffener 306 required for warpage control, a height of a memory package 106 or memory die, or a height of other components.

The auxiliary circuit board 302 may be mechanically coupled and/or electronically coupled to the primary circuit board 102 in any suitable manner. For example, the auxiliary circuit board 302 may be coupled to the primary circuit board 102 using sintering process bonding through plated through holes, hybrid bonding, solder reflow, and/or the like.

In an illustrative embodiment, the motherboard 112 may be made of a similar material, similar design, and similar dimensions as the circuit board 102, a description of which will not be repeated in the interest of clarity. The motherboard 112 may interface with additional components not shown, such as memory packages, power components, additional integrated circuit components 101, GPUs, NPUs, and/or the like. Additional components are also not shown, such as an integrated heat sink (IHS) on the integrated circuit component 101, a heat sink with fan, etc.

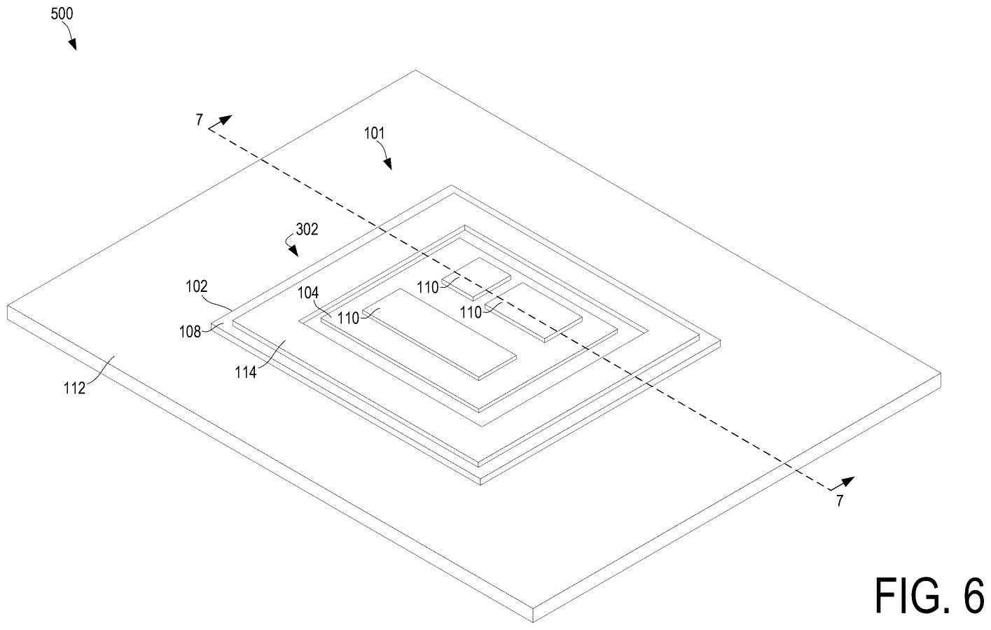

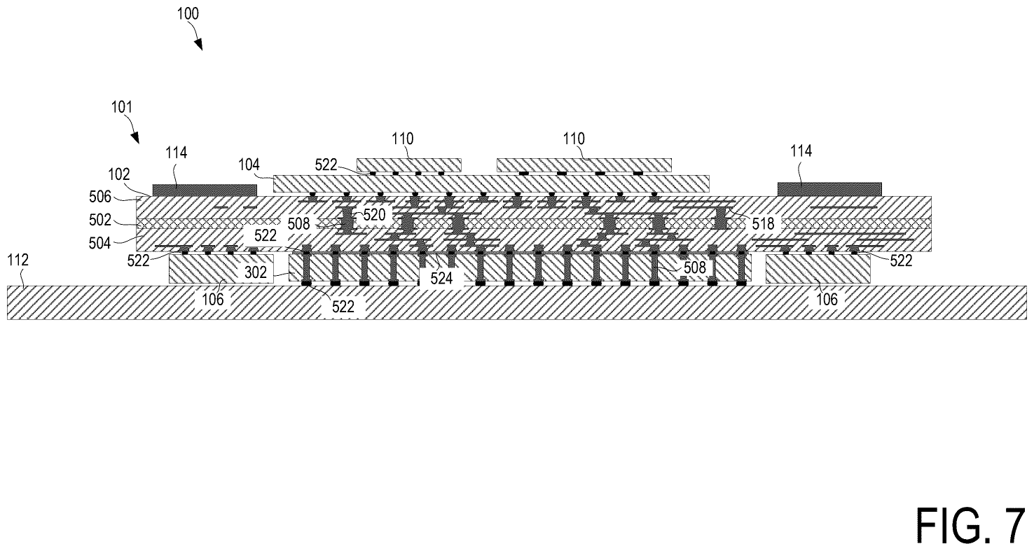

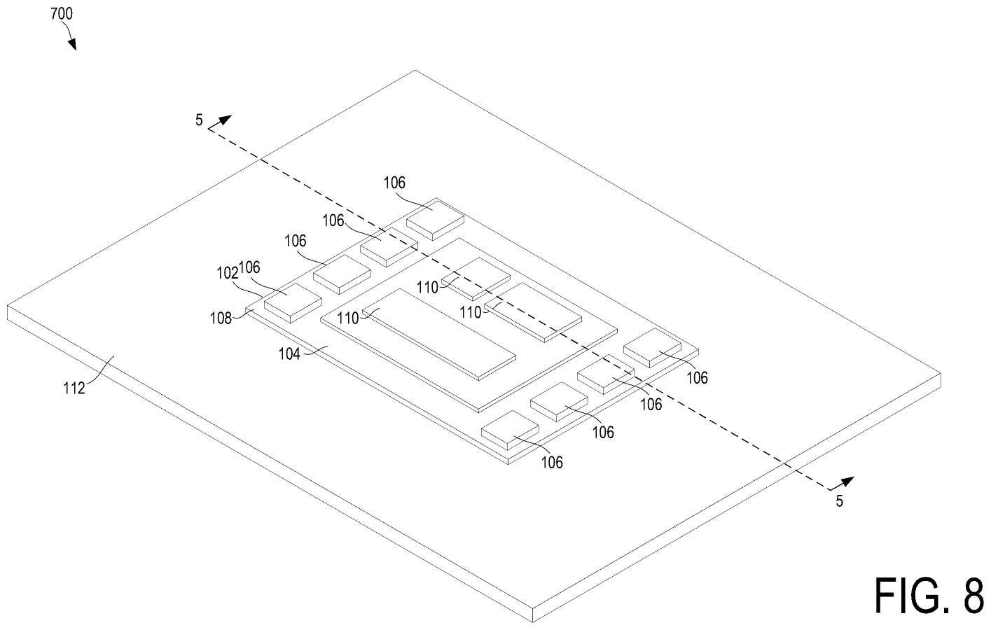

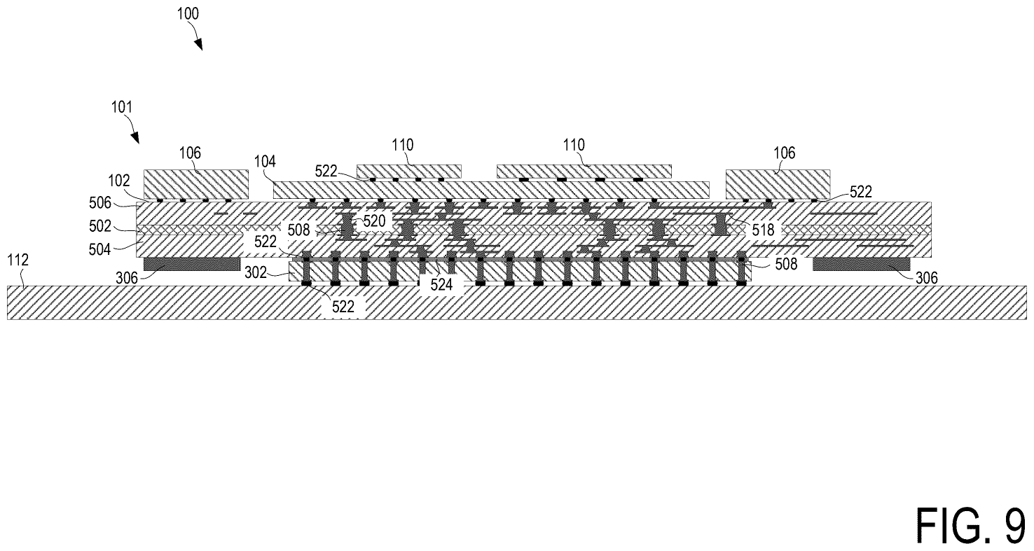

It should be appreciated that there are possible variations of the integrated circuit component 101 described above. For example, in one embodiment, rather than a primary circuit board 102 with a stiffener 114 on the top side 108 and a stiffener 306 on the bottom side 304, an integrated circuit component 101 may have a primary circuit board 102 with a stiffener 114 on the top side 108 and no stiffener on the bottom side 304, as shown in FIGS. 6 and 7. In the embodiment shown, the space on the bottom side 304 of the primary circuit board 102 is used for memory packages 106. In another embodiment, an integrated circuit component 101 may have a primary circuit board 102 with no stiffener 114 on the top side 108 and a stiffener 306 on the bottom side 304, as shown in FIGS. 8 and 9.

The techniques described above can provide several advantages in various embodiments. For example, in some embodiments, the same primary circuit board 102 layout may be used with different auxiliary circuit boards 302, allowing for integrated circuit packages 101 that can be compatible with different motherboards 112 with the same primary circuit board 102 and/or layout of the dies 104, 110 and/or packages 106. For example, the same primary circuit board 102 and/or layout of the dies 104, 110 and/or packages 106 may be used for an integrated circuit package 101 compatible with a motherboard with a certain socket (e.g., a socket with a certain number of contacts and dimensions) and for an integrated circuit package 101 compatible with a motherboard with a different socket (e.g., a socket with a different number of contacts and dimensions). Each of the different sockets may have any suitable number of contacts and any suitable dimensions, such as 10-10,000 and a length and/or width of 5-150 millimeters. Additionally or alternatively, in some embodiments, the design facilitates placement of components such as DRAM packages and/or NPU devices on the integrated circuit package 101 can reduce the motherboard 112 area significantly. Additionally or alternatively, a smaller auxiliary circuit board 302 can allow board passive component placement within the package size boundary, saving some real-estate area in the board. In some embodiments, the cost of the auxiliary circuit board 302 may be less than that of the circuit board 102, due to being smaller area and/or a smaller number of layers.

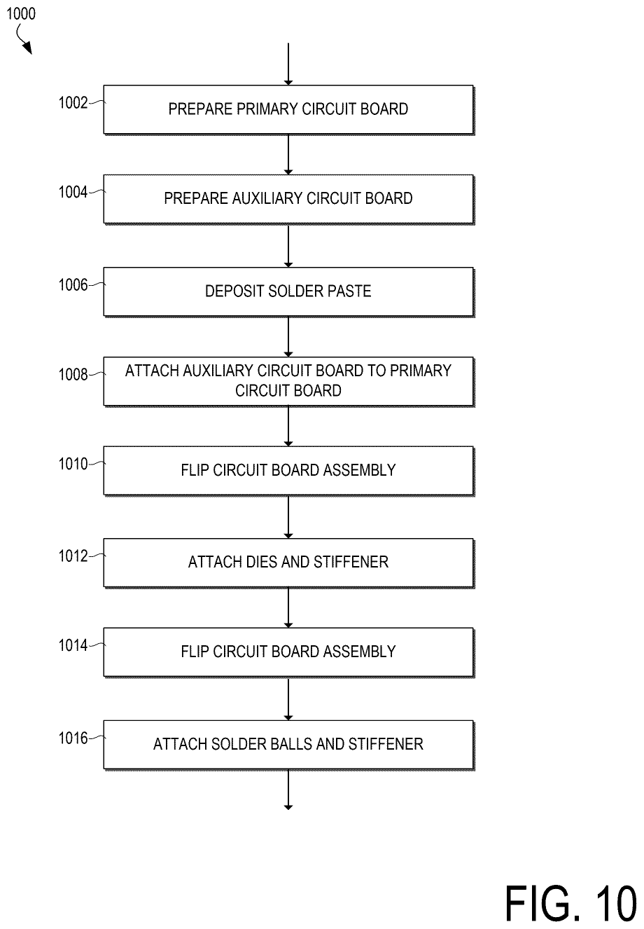

Referring now to FIG. 10, in one embodiment, a flowchart for a method 1000 for creating the integrated circuit component 101 is shown. The method 1000 may be executed by a technician and/or by one or more automated machines. In some embodiments, one or more machines may be programmed to do some or all of the steps of the method 1000. Such a machine may include, e.g., a memory, a processor, data storage, etc. The memory and/or data storage may store instructions that, when executed by the machine, cause the machine to perform some or all of the steps of the method 1000. The method 1000 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 1000 is merely one embodiment of a method to create one embodiment of a system 100 including the integrated circuit components 101, and other methods may be used to create any suitable embodiment of systems 100 with the integrated circuit components 101. In some embodiments, steps of the method 1000 may be performed in a different order than that shown in the flowchart.

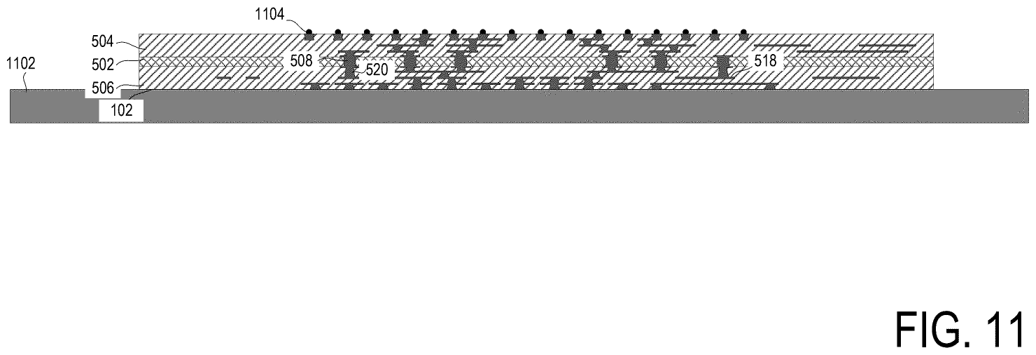

The method 1000 begins in block 1002, in which a primary circuit board 102 is prepared, such as by creating vias in a core, building up layers, adding vias and traces to the various layers, etc. The primary circuit board 102 may be mounted on a carrier 1102, as shown in FIG. 11. In block 1004, an auxiliary circuit board 302 may be prepared, using similar techniques as for the primary circuit board 102. It should be appreciated that the auxiliary circuit board 302 may have fewer layers than the primary circuit board 102 and/or may use a lower-cost process, such as larger trace width/spacing, lower-density interconnects, etc.

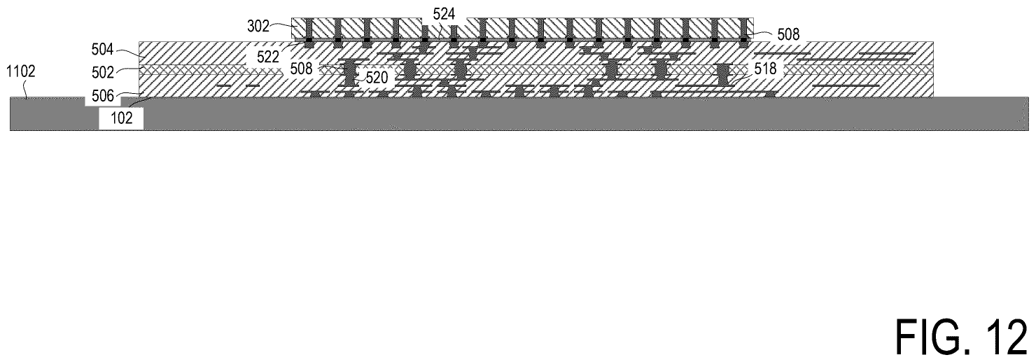

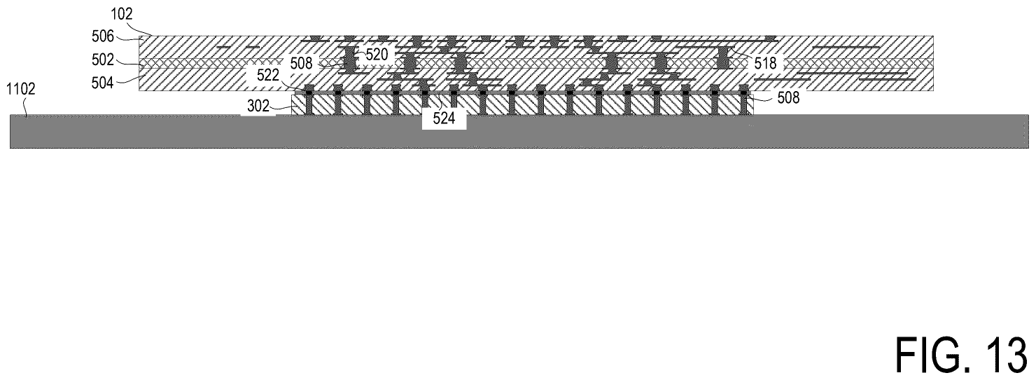

In block 1006, solder paste 1104 may be deposited on the primary circuit board 102, as shown in FIG. 11. In block 1008, the auxiliary circuit board 302 may be attached to the primary circuit board 102, such as by placing the auxiliary circuit board 302 on the primary circuit board 102 and performing a solder reflow process to turn the solder paste 1104 into conductive contacts 522 electronically coupling the primary circuit board 102 and the auxiliary circuit board 302, as shown in FIG. 12. In some embodiments, an adhesive 524, such as epoxy, is used to underfill the space between the primary circuit board 102 and the auxiliary circuit board 302. In block 1010, the assembly of circuit boards 102, 302 may be flipped over, as shown in FIG. 13.

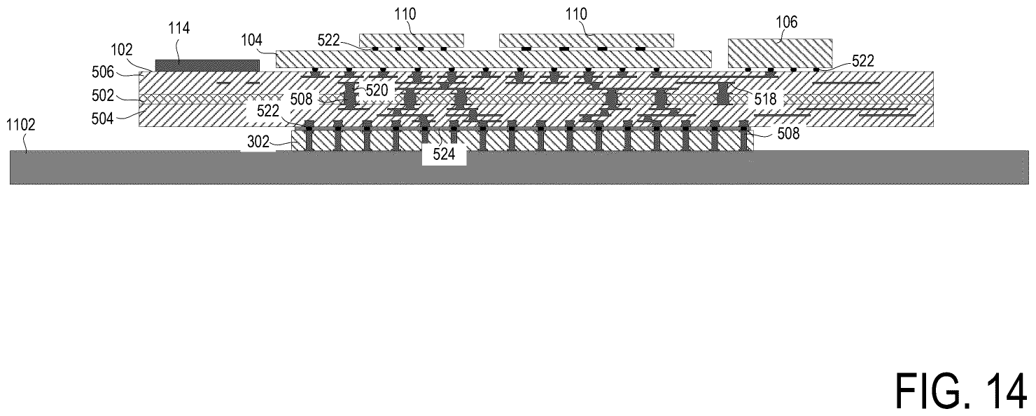

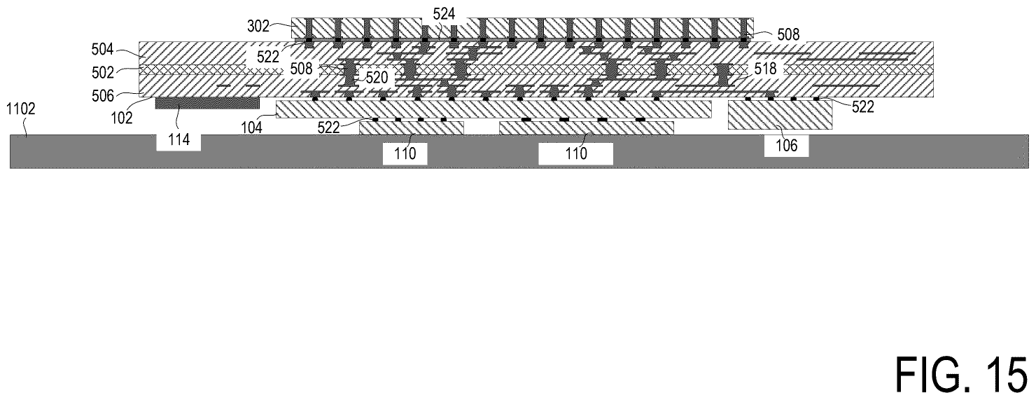

In block 1012, the dies 104, 110, memory packages 106, and stiffener 114 may be attached, as shown in FIG. 14. In block 1014, the circuit board assembly may be flipped back over, as shown in FIG. 15.

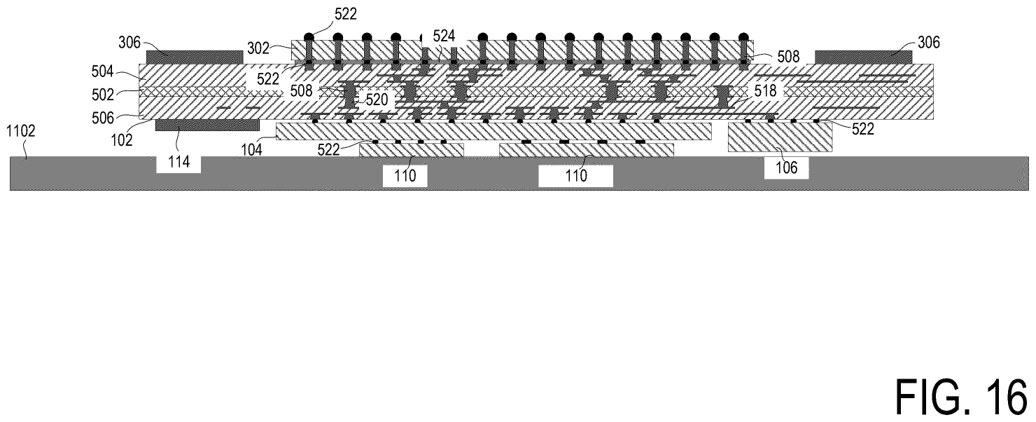

In block 1016, solder balls to act as conductive contacts 522 may be attached to the auxiliary circuit board 302, and a stiffener 306 may be attached to the bottom side 304 of the primary circuit board 102, as shown in FIG. 16.

After the conductive contacts 522 and stiffener 306 are attached, additional processing and assembly of the system may proceed. For example, an integrated heat spreader may be added, the integrated circuit component 101 may be mounted on a motherboard 112, a heat sink and fan may be added, etc.

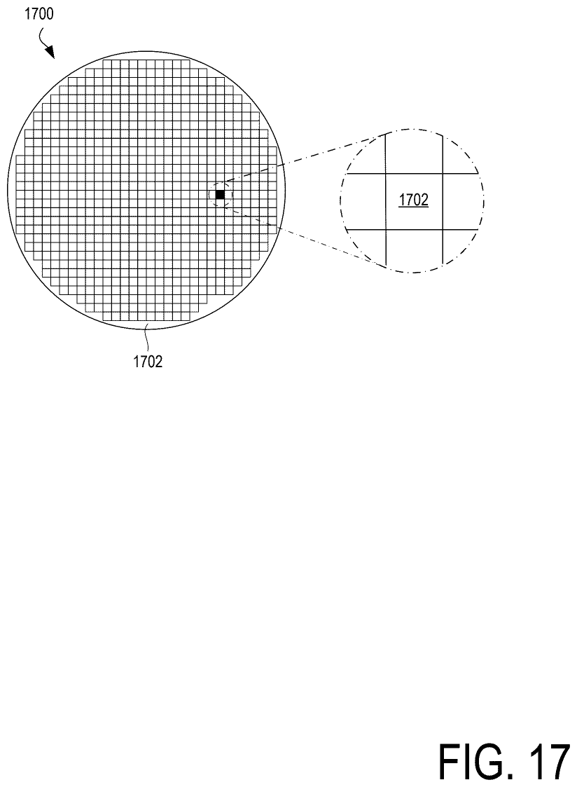

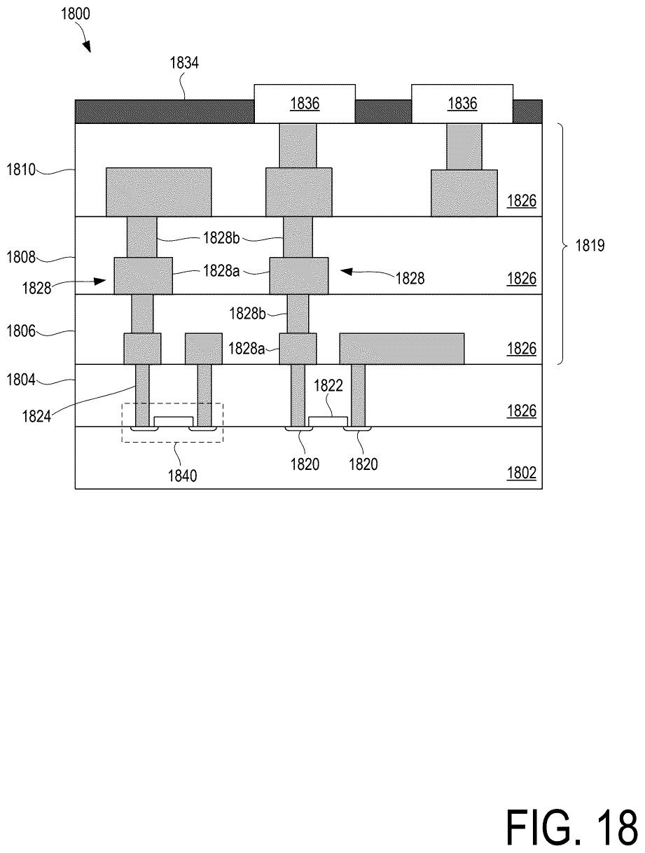

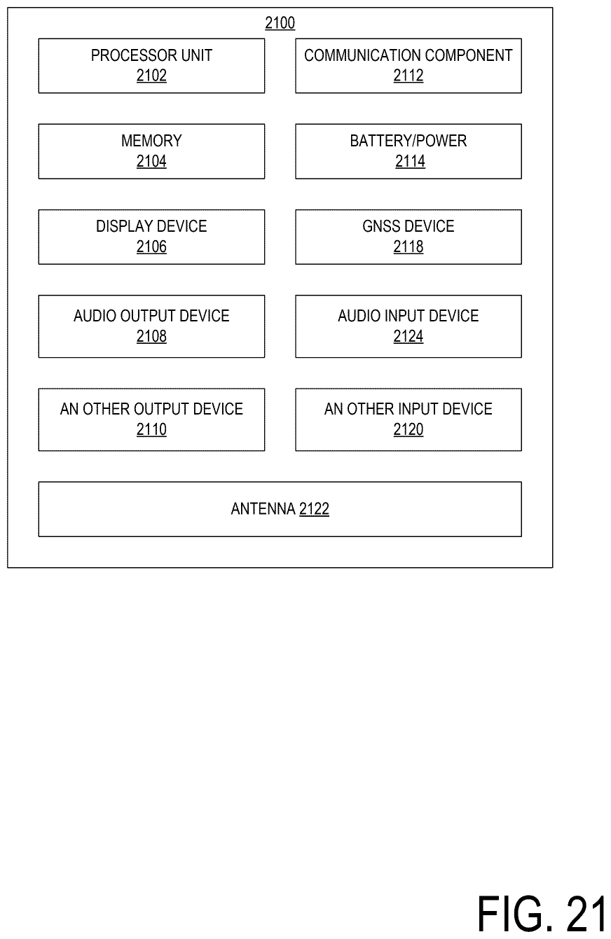

FIG. 17 is a top view of a wafer 1700 and dies 1702 that may be included in any of the integrated circuit components 101 disclosed herein (e.g., as any suitable ones of the dies 104, 110). The wafer 1700 may be composed of semiconductor material and may include one or more dies 1702 having integrated circuit structures formed on a surface of the wafer 1700. The individual dies 1702 may be a repeating unit of an integrated circuit product that includes any suitable integrated circuit. After the fabrication of the semiconductor product is complete, the wafer 1700 may undergo a singulation process in which the dies 1702 are separated from one another to provide discrete “chips” of the integrated circuit product. The die 1702 may be any of the dies 104, 110 disclosed herein. The die 1702 may include one or more transistors (e.g., some of the transistors 1840 of FIG. 18, discussed below), supporting circuitry to route electrical signals to the transistors, passive components (e.g., signal traces, resistors, capacitors, or inductors), and/or any other integrated circuit components. In some embodiments, the wafer 1700 or the die 1702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1702. For example, a memory array formed by multiple memory devices may be formed on a same die 1702 as a processor unit (e.g., the processor unit 2102 of FIG. 21) or other logic that is configured to store information in the memory devices or execute instructions stored in the memory array. Various ones of the integrated circuit components 101 disclosed herein may be manufactured using a die-to-wafer assembly technique in which some dies 104, 110 are attached to a wafer 1700 that include others of the dies 104, 110, and the wafer 1700 is subsequently singulated.

FIG. 18 is a cross-sectional side view of an integrated circuit device 1800 that may be included in any of the integrated circuit components 101 disclosed herein (e.g., in any of the dies 104, 110). One or more of the integrated circuit devices 1800 may be included in one or more dies 1702 (FIG. 17). The integrated circuit device 1800 may be formed on a die substrate 1802 (e.g., the wafer 1700 of FIG. 17) and may be included in a die (e.g., the die 1702 of FIG. 17). The die substrate 1802 may be a semiconductor substrate composed of semiconductor material systems including, for example, n-type or p-type materials systems (or a combination of both). The die substrate 1802 may include, for example, a crystalline substrate formed using a bulk silicon or a silicon-on-insulator (SOI) substructure. In some embodiments, the die substrate 1802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1802. Although a few examples of materials from which the die substrate 1802 may be formed are described here, any material that may serve as a foundation for an integrated circuit device 1800 may be used. The die substrate 1802 may be part of a singulated die (e.g., the dies 1702 of FIG. 17) or a wafer (e.g., the wafer 1700 of FIG. 17).

The integrated circuit device 1800 may include one or more device layers 1804 disposed on the die substrate 1802. The device layer 1804 may include features of one or more transistors 1840 (e.g., metal oxide semiconductor field-effect transistors (MOSFETs)) formed on the die substrate 1802. The transistors 1840 may include, for example, one or more source and/or drain (S/D) regions 1820, a gate 1822 to control current flow between the S/D regions 1820, and one or more S/D contacts 1824 to route electrical signals to/from the S/D regions 1820. The transistors 1840 may include additional features not depicted for the sake of clarity, such as device isolation regions, gate contacts, and the like. The transistors 1840 are not limited to the type and configuration depicted in FIG. 18 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

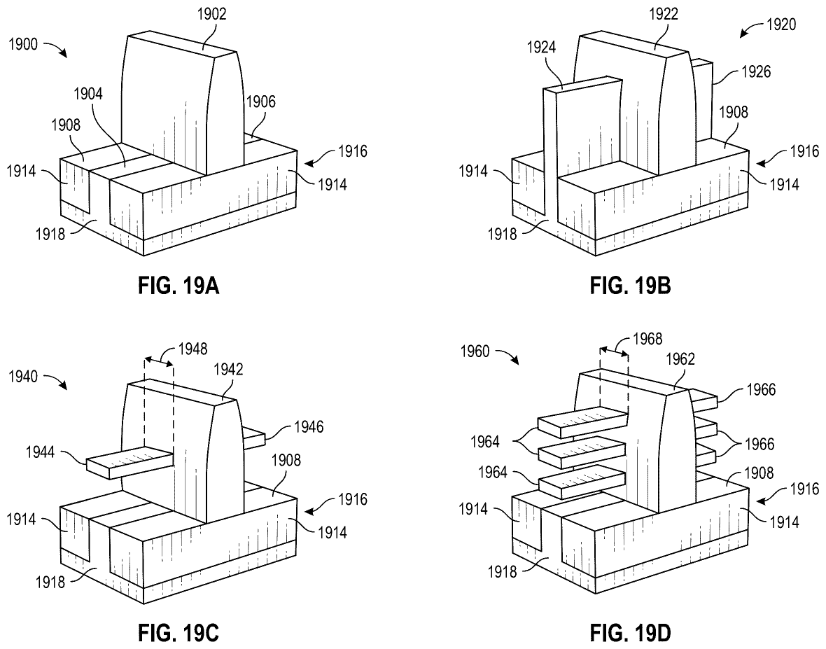

FIGS. 19A-19D are simplified perspective views of example planar, FinFET, gate-all-around, and stacked gate-all-around transistors. The transistors illustrated in FIGS. 19A-19D are formed on a substrate 1916 having a surface 1908. Isolation regions 1914 separate the source and drain regions of the transistors from other transistors and from a bulk region 1918 of the substrate 1916.

FIG. 19A is a perspective view of an example planar transistor 1900 comprising a gate 1902 that controls current flow between a source region 1904 and a drain region 1906. The transistor 1900 is planar in that the source region 1904 and the drain region 1906 are planar with respect to the substrate surface 1908.

FIG. 19B is a perspective view of an example FinFET transistor 1920 comprising a gate 1922 that controls current flow between a source region 1924 and a drain region 1926. The transistor 1920 is non-planar in that the source region 1924 and the drain region 1926 comprise “fins” that extend upwards from the substrate surface 1928. As the gate 1922 encompasses three sides of the semiconductor fin that extends from the source region 1924 to the drain region 1926, the transistor 1920 can be considered a tri-gate transistor. FIG. 19B illustrates one S/D fin extending through the gate 1922, but multiple S/D fins can extend through the gate of a FinFET transistor.

FIG. 19C is a perspective view of a gate-all-around (GAA) transistor 1940 comprising a gate 1942 that controls current flow between a source region 1944 and a drain region 1946. The transistor 1940 is non-planar in that the source region 1944 and the drain region 1946 are elevated from the substrate surface 1928.

FIG. 19D is a perspective view of a GAA transistor 1960 comprising a gate 1962 that controls current flow between multiple elevated source regions 1964 and multiple elevated drain regions 1966. The transistor 1960 is a stacked GAA transistor as the gate controls the flow of current between multiple elevated S/D regions stacked on top of each other. The transistors 1940 and 1960 are considered gate-all-around transistors as the gates encompass all sides of the semiconductor portions that extends from the source regions to the drain regions. The transistors 1940 and 1960 can alternatively be referred to as nanowire, nanosheet, or nanoribbon transistors depending on the width (e.g., widths 1948 and 1968 of transistors 1940 and 1960, respectively) of the semiconductor portions extending through the gate.

Returning to FIG. 18, a transistor 1840 may include a gate 1822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1840 along the source-channel-drain direction, the gate electrode may consist of a U-shaped structure that includes a bottom portion substantially parallel to the surface of the die substrate 1802 and two sidewall portions that are substantially perpendicular to the top surface of the die substrate 1802. In other embodiments, at least one of the metal layers that form the gate electrode may simply be a planar layer that is substantially parallel to the top surface of the die substrate 1802 and does not include sidewall portions substantially perpendicular to the top surface of the die substrate 1802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1820 may be formed within the die substrate 1802 adjacent to the gate 1822 of individual transistors 1840. The S/D regions 1820 may be formed using an implantation/diffusion process or an etching/deposition process, for example. In the former process, dopants such as boron, aluminum, antimony, phosphorous, or arsenic may be ion-implanted into the die substrate 1802 to form the S/D regions 1820. An annealing process that activates the dopants and causes them to diffuse farther into the die substrate 1802 may follow the ion-implantation process. In the latter process, the die substrate 1802 may first be etched to form recesses at the locations of the S/D regions 1820. An epitaxial deposition process may then be carried out to fill the recesses with material that is used to fabricate the S/D regions 1820. In some implementations, the S/D regions 1820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1820 may be formed using one or more alternate semiconductor materials such as germanium or a group III-V material or alloy. In further embodiments, one or more layers of metal and/or metal alloys may be used to form the S/D regions 1820.

Electrical signals, such as power and/or input/output (I/O) signals, may be routed to and/or from the devices (e.g., transistors 1840) of the device layer 1804 through one or more interconnect layers disposed on the device layer 1804 (illustrated in FIG. 18 as interconnect layers 1806-1810). For example, electrically conductive features of the device layer 1804 (e.g., the gate 1822 and the S/D contacts 1824) may be electrically coupled with the interconnect structures 1828 of the interconnect layers 1806-1810. The one or more interconnect layers 1806-1810 may form a metallization stack (also referred to as an “ILD stack”) 1819 of the integrated circuit device 1800.

The interconnect structures 1828 may be arranged within the interconnect layers 1806-1810 to route electrical signals according to a wide variety of designs; in particular, the arrangement is not limited to the particular configuration of interconnect structures 1828 depicted in FIG. 18. Although a particular number of interconnect layers 1806-1810 is depicted in FIG. 18, embodiments of the present disclosure include integrated circuit devices having more or fewer interconnect layers than depicted.

In some embodiments, the interconnect structures 1828 may include lines 1828a and/or vias 1828b filled with an electrically conductive material such as a metal. The lines 1828a may be arranged to route electrical signals in a direction of a plane that is substantially parallel with a surface of the die substrate 1802 upon which the device layer 1804 is formed. For example, the lines 1828a may route electrical signals in a direction in and out of the page and/or in a direction across the page. The vias 1828b may be arranged to route electrical signals in a direction of a plane that is substantially perpendicular to the surface of the die substrate 1802 upon which the device layer 1804 is formed. In some embodiments, the vias 1828b may electrically couple lines 1828a of different interconnect layers 1806-1810 together.

The interconnect layers 1806-1810 may include a dielectric material 1826 disposed between the interconnect structures 1828, as shown in FIG. 18. In some embodiments, dielectric material 1826 disposed between the interconnect structures 1828 in different ones of the interconnect layers 1806-1810 may have different compositions; in other embodiments, the composition of the dielectric material 1826 between different interconnect layers 1806-1810 may be the same. The device layer 1804 may include a dielectric material 1826 disposed between the transistors 1840 and a bottom layer of the metallization stack as well. The dielectric material 1826 included in the device layer 1804 may have a different composition than the dielectric material 1826 included in the interconnect layers 1806-1810; in other embodiments, the composition of the dielectric material 1826 in the device layer 1804 may be the same as a dielectric material 1826 included in any one of the interconnect layers 1806-1810.

A first interconnect layer 1806 (referred to as Metal 1 or “M1”) may be formed directly on the device layer 1804. In some embodiments, the first interconnect layer 1806 may include lines 1828a and/or vias 1828b, as shown. The lines 1828a of the first interconnect layer 1806 may be coupled with contacts (e.g., the S/D contacts 1824) of the device layer 1804. The vias 1828b of the first interconnect layer 1806 may be coupled with the lines 1828a of a second interconnect layer 1808.

The second interconnect layer 1808 (referred to as Metal 2 or “M2”) may be formed directly on the first interconnect layer 1806. In some embodiments, the second interconnect layer 1808 may include via 1828b to couple the lines 1828 of the second interconnect layer 1808 with the lines 1828a of a third interconnect layer 1810. Although the lines 1828a and the vias 1828b are structurally delineated with a line within individual interconnect layers for the sake of clarity, the lines 1828a and the vias 1828b may be structurally and/or materially contiguous (e.g., simultaneously filled during a dual-damascene process) in some embodiments.

The third interconnect layer 1810 (referred to as Metal 3 or “M3”) (and additional interconnect layers, as desired) may be formed in succession on the second interconnect layer 1808 according to similar techniques and configurations described in connection with the second interconnect layer 1808 or the first interconnect layer 1806. In some embodiments, the interconnect layers that are “higher up” in the metallization stack 1819 in the integrated circuit device 1800 (i.e., farther away from the device layer 1804) may be thicker that the interconnect layers that are lower in the metallization stack 1819, with lines 1828a and vias 1828b in the higher interconnect layers being thicker than those in the lower interconnect layers.

The integrated circuit device 1800 may include a solder resist material 1834 (e.g., polyimide or similar material) and one or more conductive contacts 1836 formed on the interconnect layers 1806-1810. In FIG. 18, the conductive contacts 1836 are illustrated as taking the form of bond pads. The conductive contacts 1836 may be electrically coupled with the interconnect structures 1828 and configured to route the electrical signals of the transistor(s) 1840 to external devices. For example, solder bonds may be formed on the one or more conductive contacts 1836 to mechanically and/or electrically couple an integrated circuit die including the integrated circuit device 1800 with another component (e.g., a printed circuit board). The integrated circuit device 1800 may include additional or alternate structures to route the electrical signals from the interconnect layers 1806-1810; for example, the conductive contacts 1836 may include other analogous features (e.g., posts) that route the electrical signals to external components. The conductive contacts 1836 may serve as any of the conductive contacts 522, as appropriate.

In some embodiments in which the integrated circuit device 1800 is a double-sided die, the integrated circuit device 1800 may include another metallization stack (not shown) on the opposite side of the device layer(s) 1804. This metallization stack may include multiple interconnect layers as discussed above with reference to the interconnect layers 1806-1810, to provide conductive pathways (e.g., including conductive lines and vias) between the device layer(s) 1804 and additional conductive contacts (not shown) on the opposite side of the integrated circuit device 1800 from the conductive contacts 1836. These additional conductive contacts may serve as any of the conductive contacts 522, as appropriate.

In other embodiments in which the integrated circuit device 1800 is a double-sided die, the integrated circuit device 1800 may include one or more through silicon vias (TSVs) through the die substrate 1802; these TSVs may make contact with the device layer(s) 1804, and may provide conductive pathways between the device layer(s) 1804 and additional conductive contacts (not shown) on the opposite side of the integrated circuit device 1800 from the conductive contacts 1836. These additional conductive contacts may serve as any of the conductive contacts 522, as appropriate. In some embodiments, TSVs extending through the substrate can be used for routing power and ground signals from conductive contacts on the opposite side of the integrated circuit device 1800 from the conductive contacts 1836 to the transistors 1840 and any other components integrated into the die 1800, and the metallization stack 1819 can be used to route I/O signals from the conductive contacts 1836 to transistors 1840 and any other components integrated into the die 1800.

Multiple integrated circuit devices 1800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

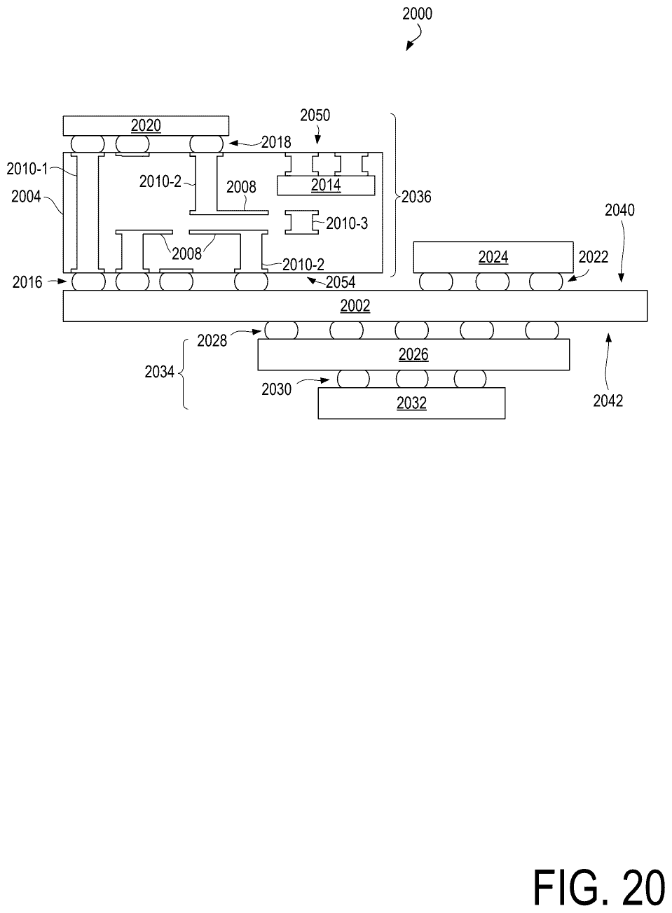

FIG. 20 is a cross-sectional side view of an integrated circuit device assembly 2000 that may include any of the integrated circuit components 101 disclosed herein. In some embodiments, the integrated circuit device assembly 2000 may be an integrated circuit component 101. The integrated circuit device assembly 2000 includes a number of components disposed on a circuit board 2002 (which may be a motherboard, system board, mainboard, etc.). The integrated circuit device assembly 2000 includes components disposed on a first face 2040 of the circuit board 2002 and an opposing second face 2042 of the circuit board 2002; generally, components may be disposed on one or both faces 2040 and 2042. Any of the integrated circuit components discussed below with reference to the integrated circuit device assembly 2000 may take the form of any suitable ones of the embodiments of the integrated circuit components 101 disclosed herein.

In some embodiments, the circuit board 2002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2002. In other embodiments, the circuit board 2002 may be a non-PCB substrate. In some embodiments the circuit board 2002 may be, for example, the circuit board 102 or 302. The integrated circuit device assembly 2000 illustrated in FIG. 20 includes a package-on-interposer structure 2036 coupled to the first face 2040 of the circuit board 2002 by coupling components 2016. The coupling components 2016 may electrically and mechanically couple the package-on-interposer structure 2036 to the circuit board 2002, and may include solder balls (as shown in FIG. 20), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 2016 may serve as the coupling components illustrated or described for any of the substrate assembly or substrate assembly components described herein, as appropriate.

The package-on-interposer structure 2036 may include an integrated circuit component 2020 coupled to an interposer 2004 by coupling components 2018. The coupling components 2018 may take any suitable form for the application, such as the forms discussed above with reference to the coupling components 2016. Although a single integrated circuit component 2020 is shown in FIG. 20, multiple integrated circuit components may be coupled to the interposer 2004; indeed, additional interposers may be coupled to the interposer 2004. The interposer 2004 may provide an intervening substrate used to bridge the circuit board 2002 and the integrated circuit component 2020.

The integrated circuit component 2020 may be a packaged or unpacked integrated circuit product that includes one or more integrated circuit dies (e.g., the die 1702 of FIG. 17, the integrated circuit device 1800 of FIG. 18) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2020, a single monolithic integrated circuit die comprises solder bumps attached to contacts on the die. The solder bumps allow the die to be directly attached to the interposer 2004. The integrated circuit component 2020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2004 may spread connections to a wider pitch or reroute a connection to a different connection. For example, the interposer 2004 may couple the integrated circuit component 2020 to a set of ball grid array (BGA) conductive contacts of the coupling components 2016 for coupling to the circuit board 2002. In the embodiment illustrated in FIG. 20, the integrated circuit component 2020 and the circuit board 2002 are attached to opposing sides of the interposer 2004; in other embodiments, the integrated circuit component 2020 and the circuit board 2002 may be attached to a same side of the interposer 2004. In some embodiments, three or more components may be interconnected by way of the interposer 2004.

In some embodiments, the interposer 2004 may be formed as a PCB, including multiple metal layers separated from one another by layers of dielectric material and interconnected by electrically conductive vias. In some embodiments, the interposer 2004 may be formed of an epoxy resin, a fiberglass-reinforced epoxy resin, an epoxy resin with inorganic fillers, a ceramic material, or a polymer material such as polyimide. In some embodiments, the interposer 2004 may be formed of alternate rigid or flexible materials that may include the same materials described above for use in a semiconductor substrate, such as silicon, germanium, and other group III-V and group IV materials. The interposer 2004 may include metal interconnects 2008 and vias 2010, including but not limited to through hole vias 2010-1 (that extend from a first face 2050 of the interposer 2004 to a second face 2054 of the interposer 2004), blind vias 2010-2 (that extend from the first or second faces 2050 or 2054 of the interposer 2004 to an internal metal layer), and buried vias 2010-3 (that connect internal metal layers).

In some embodiments, the interposer 2004 can comprise a silicon interposer. Through silicon vias (TSV) extending through the silicon interposer can connect connections on a first face of a silicon interposer to an opposing second face of the silicon interposer. In some embodiments, an interposer 2004 comprising a silicon interposer can further comprise one or more routing layers to route connections on a first face of the interposer 2004 to an opposing second face of the interposer 2004.

The interposer 2004 may further include embedded devices 2014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2004. The package-on-interposer structure 2036 may take the form of any of the package-on-interposer structures known in the art.

The integrated circuit device assembly 2000 may include an integrated circuit component 2024 coupled to the first face 2040 of the circuit board 2002 by coupling components 2022. The coupling components 2022 may take the form of any of the embodiments discussed above with reference to the coupling components 2016, and the integrated circuit component 2024 may take the form of any of the embodiments discussed above with reference to the integrated circuit component 2020.

The integrated circuit device assembly 2000 illustrated in FIG. 20 includes a package-on-package structure 2034 coupled to the second face 2042 of the circuit board 2002 by coupling components 2028. The package-on-package structure 2034 may include an integrated circuit component 2026 and an integrated circuit component 2032 coupled together by coupling components 2030 such that the integrated circuit component 2026 is disposed between the circuit board 2002 and the integrated circuit component 2032. The coupling components 2028 and 2030 may take the form of any of the embodiments of the coupling components 2016 discussed above, and the integrated circuit components 2026 and 2032 may take the form of any of the embodiments of the integrated circuit component 2020 discussed above. The package-on-package structure 2034 may be configured in accordance with any of the package-on-package structures known in the art.

FIG. 21 is a block diagram of an example electrical device 2100 that may include one or more of the integrated circuit components 101 disclosed herein. For example, any suitable ones of the components of the electrical device 2100 may include one or more of the integrated circuit device assemblies 2000, integrated circuit components 2020, integrated circuit devices 1800, or integrated circuit dies 1702 disclosed herein, and may be arranged in any of the integrated circuit components 101 disclosed herein. A number of components are illustrated in FIG. 21 as included in the electrical device 2100, but any one or more of these components may be omitted or duplicated, as suitable for the application. In some embodiments, some or all of the components included in the electrical device 2100 may be attached to one or more motherboards mainboards, or system boards. In some embodiments, one or more of these components are fabricated onto a single system-on-a-chip (SoC) die.

Additionally, in various embodiments, the electrical device 2100 may not include one or more of the components illustrated in FIG. 21, but the electrical device 2100 may include interface circuitry for coupling to the one or more components. For example, the electrical device 2100 may not include a display device 2106, but may include display device interface circuitry (e.g., a connector and driver circuitry) to which a display device 2106 may be coupled. In another set of examples, the electrical device 2100 may not include an audio input device 2124 or an audio output device 2108, but may include audio input or output device interface circuitry (e.g., connectors and supporting circuitry) to which an audio input device 2124 or audio output device 2108 may be coupled.

The electrical device 2100 may include one or more processor units 2102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2100 may include a memory 2104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2104 may include memory that is located on the same integrated circuit die as the processor unit 2102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2100 can comprise one or more processor units 2102 that are heterogeneous or asymmetric to another processor unit 2102 in the electrical device 2100. There can be a variety of differences between the processing units 2102 in a system in terms of a spectrum of metrics of merit including architectural, microarchitectural, thermal, power consumption characteristics, and the like. These differences can effectively manifest themselves as asymmetry and heterogeneity among the processor units 2102 in the electrical device 2100.

In some embodiments, the electrical device 2100 may include a communication component 2112 (e.g., one or more communication components). For example, the communication component 2112 can manage wireless communications for the transfer of data to and from the electrical device 2100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2112 may operate in accordance with other wireless protocols in other embodiments. The electrical device 2100 may include an antenna 2122 to facilitate wireless communications and/or to receive other wireless communications (such as AM or FM radio transmissions).

In some embodiments, the communication component 2112 may manage wired communications, such as electrical, optical, or any other suitable communication protocols (e.g., IEEE 802.3 Ethernet standards). As noted above, the communication component 2112 may include multiple communication components. For instance, a first communication component 2112 may be dedicated to shorter-range wireless communications such as Wi-Fi or Bluetooth, and a second communication component 2112 may be dedicated to longer-range wireless communications such as global positioning system (GPS), EDGE, GPRS, CDMA, WiMAX, LTE, EV-DO, or others. In some embodiments, a first communication component 2112 may be dedicated to wireless communications, and a second communication component 2112 may be dedicated to wired communications.

The electrical device 2100 may include battery/power circuitry 2114. The battery/power circuitry 2114 may include one or more energy storage devices (e.g., batteries or capacitors) and/or circuitry for coupling components of the electrical device 2100 to an energy source separate from the electrical device 2100 (e.g., AC line power).

The electrical device 2100 may include a display device 2106 (or corresponding interface circuitry, as discussed above). The display device 2106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2100 may include an audio output device 2108 (or corresponding interface circuitry, as discussed above). The audio output device 2108 may include any embedded or wired or wirelessly connected external device that generates an audible indicator, such as speakers, headsets, or earbuds.

The electrical device 2100 may include an audio input device 2124 (or corresponding interface circuitry, as discussed above). The audio input device 2124 may include any embedded or wired or wirelessly connected device that generates a signal representative of a sound, such as microphones, microphone arrays, or digital instruments (e.g., instruments having a musical instrument digital interface (MIDI) output). The electrical device 2100 may include a Global Navigation Satellite System (GNSS) device 2118 (or corresponding interface circuitry, as discussed above), such as a Global Positioning System (GPS) device. The GNSS device 2118 may be in communication with a satellite-based system and may determine a geolocation of the electrical device 2100 based on information received from one or more GNSS satellites, as known in the art.

The electrical device 2100 may include an other output device 2110 (or corresponding interface circuitry, as discussed above). Examples of the other output device 2110 may include an audio codec, a video codec, a printer, a wired or wireless transmitter for providing information to other devices, or an additional storage device.

The electrical device 2100 may include an other input device 2120 (or corresponding interface circuitry, as discussed above). Examples of the other input device 2120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2100 may be any other electronic device that processes data. In some embodiments, the electrical device 2100 may comprise multiple discrete physical components. Given the range of devices that the electrical device 2100 can be manifested as in various embodiments, in some embodiments, the electrical device 2100 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising an integrated circuit package comprising a first circuit board comprising a first side and a second side opposite the first side; one or more integrated circuit dies mounted on the first side of the first circuit board; a second circuit board comprising a first side and second side opposite the first side, wherein the first side of the second circuit board is mechanically and electronically coupled to the second side of the first circuit board; and an array of electrical contacts mounted on the second side of the second circuit board to interface with a motherboard.

Example 2 includes the subject matter of Example 1, and wherein an area of the second circuit board is less than an area of the first circuit board.

Example 3 includes the subject matter of any of Examples 1 and 2, and wherein the area of the second circuit board is less than two thirds of the area of the first circuit board.

Example 4 includes the subject matter of any of Examples 1-3, and further including a first stiffener mounted on the first side of the first circuit board and a second stiffener mounted on the second side of the first circuit board.

Example 5 includes the subject matter of any of Examples 1-4, and wherein the second stiffener surrounds the second circuit board on the second side of the first circuit board.

Example 6 includes the subject matter of any of Examples 1-5, and further including a stiffener mounted on the first side of the first circuit board, wherein there is no stiffener mounted on the second side of the first circuit board.

Example 7 includes the subject matter of any of Examples 1-6, and further including a stiffener mounted on the second side of the first circuit board, wherein there is no stiffener mounted on the first side of the first circuit board.

Example 8 includes the subject matter of any of Examples 1-7, and further including a stiffener mounted on the first side of the first circuit board and one or more integrated circuit dies mounted on the second side of the first circuit board.

Example 9 includes the subject matter of any of Examples 1-8, and wherein the one or more integrated circuit dies mounted on the second side of the first circuit board are one or more memory dies.

Example 10 includes the subject matter of any of Examples 1-9, and wherein the one or more integrated circuit dies mounted on the first side of the first circuit board comprise one or more processor dies and one or more memory dies.

Example 11 includes the subject matter of any of Examples 1-10, and further including one or more memory packages mounted on the first side of the first circuit board.

Example 12 includes the subject matter of any of Examples 1-11, and wherein the first circuit board has six or more layers, wherein the second circuit board has four or fewer layers.

Example 13 includes the subject matter of any of Examples 1-12, and wherein the second circuit board comprises a plurality of vias, wherein individual vias of the plurality of vias extend from an electrical contact of the array of electrical contacts to a corresponding electrical contact directly on the opposite side of the second circuit board.

Example 14 includes the subject matter of any of Examples 1-13, and further including an adhesive layer bonding the second circuit board to the first circuit board.

Example 15 includes an apparatus comprising an integrated circuit package comprising means for mounting one or more integrated circuit dies, wherein the means for mounting one or more integrated circuit dies has a first area; and means for interfacing with an array of electrical contacts on a motherboard, wherein the means for interfacing with the array of electrical contacts on the motherboard has a second area, wherein the second area is less than the first area.

Example 16 includes the subject matter of Example 15, and wherein the means for mounting one or more integrated circuit dies comprises means for mounting a stiffener around the means for interfacing with an array of electrical contacts on a motherboard.

Example 17 includes the subject matter of any of Examples 15 and 16, and wherein the means for mounting one or more integrated circuit dies comprises a first circuit board, wherein the means for interfacing with an array of electrical contacts on a motherboard comprises a second circuit board.

Example 18 includes the subject matter of any of Examples 15-17, and wherein the area of the second circuit board is less than two thirds of the area of the first circuit board.

Example 19 includes the subject matter of any of Examples 15-18, and further including a first stiffener mounted on a first side of the first circuit board and a second stiffener mounted on the second side of the first circuit board.

Example 20 includes the subject matter of any of Examples 15-19, and wherein the second stiffener surrounds the second circuit board on the second side of the first circuit board.

Example 21 includes the subject matter of any of Examples 15-20, and further including a stiffener mounted on a first side of the first circuit board, wherein there is no stiffener mounted on a second side of the first circuit board.

Example 22 includes the subject matter of any of Examples 15-21, and further including a stiffener mounted on a second side of the first circuit board, wherein there is no stiffener mounted on a first side of the first circuit board.

Example 23 includes the subject matter of any of Examples 15-22, and further including a stiffener mounted on a first side of the first circuit board and one or more integrated circuit dies mounted on a second side of the first circuit board.

Example 24 includes the subject matter of any of Examples 15-23, and wherein the one or more integrated circuit dies mounted on a second side of the first circuit board are one or more memory dies.

Example 25 includes the subject matter of any of Examples 15-24, and wherein the one or more integrated circuit dies mounted on a first side of the first circuit board comprise one or more processor dies and one or more memory dies.

Example 26 includes the subject matter of any of Examples 15-25, and further including one or more memory packages mounted on a first side of the first circuit board.

Example 27 includes the subject matter of any of Examples 15-26, and wherein the first circuit board has six or more layers, wherein the second circuit board has four or fewer layers.

Example 28 includes the subject matter of any of Examples 15-27, and wherein the second circuit board comprises a plurality of vias, wherein individual vias of the plurality of vias extend from an electrical contact of the array of electrical contacts to a corresponding electrical contact directly on an opposite side of the second circuit board.

Example 29 includes the subject matter of any of Examples 15-28, and further including an adhesive layer bonding the second circuit board to the first circuit board.

Example 30 includes a method comprising manufacturing a first plurality of circuit boards, wherein individual circuit boards of the first plurality of circuit boards comprise a first side and a second side opposite the first side; mounting one or more integrated circuit dies on the first side of individual circuit boards of the first plurality of circuit boards; manufacturing a second plurality of circuit boards, wherein individual circuit boards of the second plurality of circuit boards comprise a first side and a second side opposite the first side, wherein an array of electrical contacts is mounted on the second side to interface with a first motherboard socket type; manufacturing a third plurality of circuit boards, wherein individual circuit boards of the third plurality of circuit boards comprise a first side and a second side opposite the first side, wherein an array of electrical contacts is mounted on the second side to interface with a second motherboard socket type, wherein the second motherboard socket type is different from the first motherboard socket type; mounting individual circuit boards of the second plurality of circuit boards to individual circuit boards of the first plurality of circuit boards to create a first plurality of integrated circuit packages; and mounting individual circuit boards of the third plurality of circuit boards to individual circuit boards of the first plurality of circuit boards to create a second plurality of integrated circuit packages.

Example 31 includes the subject matter of Example 30, and further including mating individual integrated circuit packages of the first plurality of integrated circuit packages with a socket on a motherboard with the first motherboard socket type; and mating individual integrated circuit packages of the second plurality of integrated circuit packages with a socket on a motherboard with the second motherboard socket type.

1. An apparatus comprising:
an integrated circuit package comprising:
a first circuit board comprising a first side and a second side opposite the first side;
one or more integrated circuit dies mounted on the first side of the first circuit board;
a second circuit board comprising a first side and second side opposite the first side, wherein the first side of the second circuit board is mechanically and electronically coupled to the second side of the first circuit board; and
an array of electrical contacts mounted on the second side of the second circuit board to interface with a motherboard.

2. The apparatus of claim 1, wherein an area of the second circuit board is less than an area of the first circuit board.

3. The apparatus of claim 2, wherein the area of the second circuit board is less than two thirds of the area of the first circuit board.

4. The apparatus of claim 1, further comprising a first stiffener mounted on the first side of the first circuit board and a second stiffener mounted on the second side of the first circuit board.

5. The apparatus of claim 4, wherein the second stiffener surrounds the second circuit board on the second side of the first circuit board.

6. The apparatus of claim 1, further comprising a stiffener mounted on the first side of the first circuit board, wherein there is no stiffener mounted on the second side of the first circuit board.

7. The apparatus of claim 1, further comprising a stiffener mounted on the second side of the first circuit board, wherein there is no stiffener mounted on the first side of the first circuit board.

8. The apparatus of claim 1, further comprising a stiffener mounted on the first side of the first circuit board and one or more integrated circuit dies mounted on the second side of the first circuit board.

9. The apparatus of claim 1, wherein the one or more integrated circuit dies mounted on the second side of the first circuit board are one or more memory dies.

10. The apparatus of claim 1, wherein the one or more integrated circuit dies mounted on the first side of the first circuit board comprise one or more processor dies and one or more memory dies.

11. The apparatus of claim 1, further comprising one or more memory packages mounted on the first side of the first circuit board.

12. The apparatus of claim 1, wherein the first circuit board has six or more layers, wherein the second circuit board has four or fewer layers.

13. The apparatus of claim 1, wherein the second circuit board comprises a plurality of vias, wherein individual vias of the plurality of vias extend from an electrical contact of the array of electrical contacts to a corresponding electrical contact directly on the opposite side of the second circuit board.

14. The apparatus of claim 1, further comprising an adhesive layer bonding the second circuit board to the first circuit board.

15. An apparatus comprising:
an integrated circuit package comprising:
means for mounting one or more integrated circuit dies, wherein the means for mounting one or more integrated circuit dies has a first area; and
means for interfacing with an array of electrical contacts on a motherboard, wherein the means for interfacing with the array of electrical contacts on the motherboard has a second area, wherein the second area is less than the first area.

16. The apparatus of claim 15, wherein the means for mounting one or more integrated circuit dies comprises means for mounting a stiffener around the means for interfacing with an array of electrical contacts on a motherboard.

17. The apparatus of claim 15, wherein the means for mounting one or more integrated circuit dies comprises a first circuit board, wherein the means for interfacing with an array of electrical contacts on a motherboard comprises a second circuit board.

18. The apparatus of claim 17, wherein the area of the second circuit board is less than two thirds of the area of the first circuit board.

19. A method comprising:
manufacturing a first plurality of circuit boards, wherein individual circuit boards of the first plurality of circuit boards comprise a first side and a second side opposite the first side;
mounting one or more integrated circuit dies on the first side of individual circuit boards of the first plurality of circuit boards;
manufacturing a second plurality of circuit boards, wherein individual circuit boards of the second plurality of circuit boards comprise a first side and a second side opposite the first side, wherein an array of electrical contacts is mounted on the second side to interface with a first motherboard socket type;
manufacturing a third plurality of circuit boards, wherein individual circuit boards of the third plurality of circuit boards comprise a first side and a second side opposite the first side, wherein an array of electrical contacts is mounted on the second side to interface with a second motherboard socket type, wherein the second motherboard socket type is different from the first motherboard socket type;
mounting individual circuit boards of the second plurality of circuit boards to individual circuit boards of the first plurality of circuit boards to create a first plurality of integrated circuit packages; and
mounting individual circuit boards of the third plurality of circuit boards to individual circuit boards of the first plurality of circuit boards to create a second plurality of integrated circuit packages.

20. The method of claim 19, further comprising:
mating individual integrated circuit packages of the first plurality of integrated circuit packages with a socket on a motherboard with the first motherboard socket type; and
mating individual integrated circuit packages of the second plurality of integrated circuit packages with a socket on a motherboard with the second motherboard socket type.
